(19) United States
(12) Patent Application Publication
(10) Pub. No.: US 2015/0107880 A1
(43) Pub. Date: Apr. 23, 2015

(54) MULTILAYER PRINTED CIRCUIT BOARD

(71) Applicant: SAMSUNG ELECTRO-MECHANICS CO., LTD., Suwon (KR)

(72) Inventors: Hye Jin KIM, Yongin (KR); Hyo Seung Nam, Hwasung (KR); Tae Hong Min, Suwon (KR); Sang Hoon Kim, Gunpo (KR); Suk Hyeon Cho, Suwon (KR); Jung Han Lee, Seoul (KR)

(73) Assignee: SAMSUNG ELECTRO-MECHANICS CO., LTD., Suwon (KR)

(21) Appl. No.: 14/319,743

(22) Filed: Jun. 30, 2014

(30) Foreign Application Priority Data
Oct. 22, 2013 (KR) 10-2013-0126060

(51) Int. Cl. H05K 1/11; H05K 1/02; H05K 1/18

(52) U.S. Cl. CPC H05K 1/115; H05K 1/185; H05K 1/0298; H05K 2201/096
USPC 174/255; 174/262

(57) ABSTRACT

Disclosed herein is a multilayer printed circuit board. The multilayer printed circuit board according to the present invention includes: a stack via stacked in an upper portion of a core layer; staggered vias formed at both sides of the stack via and stacked on the core layer; and a solder resist layer stacked in a lower portion of the core layer and stacked on an insulating film except for open regions of the stack via and the staggered vias, such that the plurality of vias formed in the staggered via may increase rigidity to prevent warpage of the multilayer printed circuit board from being generated.

### CROSS REFERENCE(S) TO RELATED APPLICATIONS

This application claims the foreign priority benefit under 35 U.S.C. Section 119 of Korean Patent Application Serial No. 10-2013-0126060, entitled “Multilayer Printed Circuit Board” filed on Oct. 22, 2013, which is hereby incorporated by reference in its entirety into this application.

### BACKGROUND OF THE INVENTION

1. Technical Field

The present invention relates to a multilayer printed circuit board, and more particularly, to a multilayer printed circuit board preventing warpage during a process of manufacturing the printed circuit board.

2. Description of the Related Art

Recently, as electronic products become miniaturized, thinned, highly densified, and packaged, a printed circuit board has been fine-patterned in order to decrease a wiring density (for example, a width of the wiring or an interval between wirings).

Accordingly, in order to implement the fine patterns and increase reliability and a designed density in a multilayer printed circuit board, layers in a circuit become complicated and layers having implemented circuit patterns are formed in a multilayer, that is, the printed circuit board has a high density and a thin thickness.

In a multilayer build-up package substrate, an upper layer is required to be fine in order to transfer a signal of a device mounted on the substrate to a lower portion, and in order to mount a semiconductor package, a region in which wirings are intensified is generated in a limited area of the substrate, such that the substrate may have an asymmetrical structure.

In addition, as Central Processing Unit (CPU), application processor (AP), and the like, of the package are highly functionalized, there is no choice but the number of signals connected to the substrate is increased and the number of power supplies and grounds is increased. Here, in order to implement the build-up package having high function, a multilayer ceramic condenser (MLCC) may be embedded in a substrate, thereby making it possible to be miniaturized and packaged.

In a general build-up package substrate, both surfaces thereof are built-up based on a core layer, and vias are formed in an outer portion having a chip mounted thereon, such that rigidity is not sufficient at the edge portion of the substrate, causing warpage in the substrate.

In addition, the build-up may be constituted by fine layers; however, in this case, the rigidity of the substrate may not be maintained to cause the warpage, distortion, and the like, such that the printed circuit board having excellent rigidity with the same size may not be manufactured.

### RELATED ART DOCUMENT

### Patent Document

(Patent Document 1) Japanese Patent Laid-Open Publication No. 2001-113527

### SUMMARY OF THE INVENTION

An object of the present invention is to provide a multilayer printed circuit board capable of intensively disposing vias at edge portions of the printed circuit board to prevent warpage from being generated during a process of manufacturing the printed circuit board.

According to a first exemplary embodiment of the present invention, there is provided a multilayer printed circuit board including: a stack via stacked in an upper portion of a core layer; staggered vias formed at both sides of the stack via and stacked on the core layer; and a solder resist layer stacked in a lower portion of the core layer and stacked on an insulating film except for open regions of the stack via and the staggered vias.

In the stack via, vias adjacent to interlayer insulating films at upper and lower portions thereof may be vertically connected to each other, and in the staggered vias, vias may be disposed in a group in the upper portion of the core layer and wiring layers and the plurality of vias formed on the interlayer insulating films may be connected to each other so as to intersect with each other.

In the staggered via, diameters of vias in each insulating film may be different.

The staggered vias may be symmetrically formed based on the stack via.

The wiring layers may be connected to the plurality of vias.

The solder resist layer may have the open regions to which the wiring layers of the stack via and the staggered vias are exposed.

According to a second exemplary embodiment of the present invention, there is provided a multilayer printed circuit board including: a core layer having a cavity formed therein; a stack via stacked on the cavity; staggered vias formed at both sides of the stack via and stacked on the core layer; and a solder resist layer stacked in a lower portion of the core layer and stacked on an insulating film except for open regions of the stack via.

The cavity may include an electronic component embedded therein.

The uppermost layer of the staggered via may be provided with only the insulating film.

In the stack via, vias adjacent to interlayer insulating films at upper and lower portions thereof may be vertically connected to each other, and in the staggered vias, vias may be disposed in a group in the upper portion of the core layer and wiring layers and the plurality of vias formed on the interlayer insulating films may be connected to each other so as to intersect with each other.

The wiring layer may be a ground pattern.

### BRIEF DESCRIPTION OF THE DRAWINGS

FIG. 1 is a cross-sectional view showing a multilayer printed circuit board according to a first exemplary embodiment of the present invention;

FIG. 2 is a cross-sectional view showing a multilayer printed circuit board according to a second exemplary embodiment of the present invention;

FIG. 3 is a cross-sectional view showing a multilayer printed circuit board according to a third exemplary embodiment of the present invention; and

FIG. 4 is a cross-sectional view showing a multilayer printed circuit board according to a fourth exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

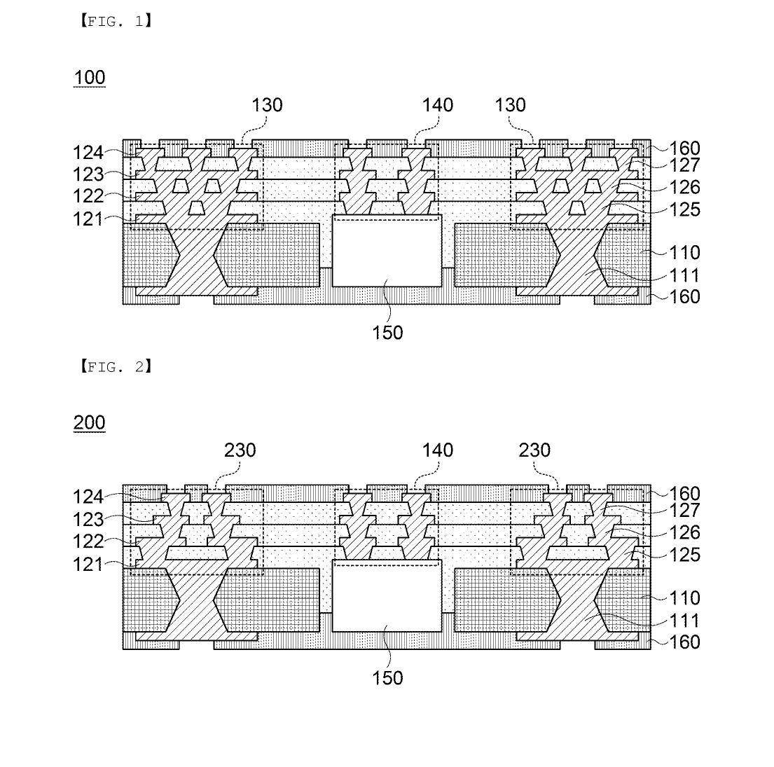

FIG. 1 is a cross-sectional view showing a multilayer printed circuit board 100 according to a first exemplary embodiment of the present invention, and FIG. 2 is a cross-sectional view showing a multilayer printed circuit board 200 according to a second exemplary embodiment of the present invention.

As shown in the drawings, the multilayer printed circuit board may include a core layer 110 which becomes a basis of a stacked build-up substrate, a stack via 140 formed in an upper portion of the core layer 110 and having a plurality of vias linearly connected to each other, staggered vias 130 formed at both sides of the core layer 110 and formed on an inner via hole (IVH) 111, and a solder resist layer 160 insulating a wiring layer from the other wiring layer and preventing corrosion of the wiring layer.

The core layer 110, which serves as a basis for stacking build-up layers including wiring layers and insulating films in the thin printed circuit board, may be applied to materials including a glass ceramic material and the existing glass fabric material, and the like.

The core layer 110 may be a basis for stacking the build-up layers capable of maintaining rigidity of the substrate and having fine patterns; however, as the wiring layers and the insulating films stacked on the core layer 110 are miniaturized, it is difficult to secure rigidity only with the core layer 110, a dummy region of an outer layer in the printed circuit board may be required to maintain the rigidity.

Therefore, the staggered vias 130 having the plurality of vias formed in the build-up layer is disposed in the other dummy region except for a portion in which the wiring layers are intensively formed, such that warpage may be minimized.

Here, in the staggered vias 130, the vias may be disposed in a group in the upper portion of the core layer 110, and wiring layers and the plurality of vias formed on interlayer insulating films may be connected to each other and built-up to form a multilayer.

The vias formed in the build-up layer may be formed so that respective center axes of the different layers are not identical to each other, and the vias are formed in the different axis line to be spaced apart from each other by a predetermined range, such that the respective center axes of the vias formed in the different build-up layers may intersect with each other.

Here, a distance in which vias formed in the staggered via 130 are spaced apart from each other may be previously designed so as to meet a desired object in consideration of a size of the printed circuit board, a degree that circuit patterns are intensified, and a position of an embedded electronic component, or may be secured so as to secure the maximum rigidity in an experiment.

For example, a diameter of a first via 125 may be defined as 50 μm or more, a diameter of a second via 126 may be defined as 35˜50 μm, a diameter of a third via 127 may be defined as 35˜15 μm, and a diameter of a fourth via may be defined as 15 μm or less. That is, the diameter of the via being formed while being built-up may be gradually decreased.

Meanwhile, the vias formed in the staggered via 130 may include vias having different diameters from that of the via of the adjacent insulating film.

Here, an upper build-up layer may have vias more than that of a lower build-up layer, the diameter of the via included in the upper build-up layer may be smaller than that of the via included in the lower build-up layer, thereby constantly maintaining the rigidity between the upper layer and the lower layer, which is more preferred.

That is, in the staggered via 130, the plurality of vias formed in the build-up layer are disposed in a dummy expect for the outer portion of the substrate vulnerable to the warpage or the region in which the wiring layers are intensified, thereby increasing the rigidity, such that an outer force generated in the core layer 110 of the multilayer printed circuit board may be dispersed to minimize the warpage phenomenon.

The vias formed in the same build-up layer in the staggered via 130 may be connected to the wiring layer, thereby hindering the warpage, and heat transferred from a laser beam during a laser through hole process by a laser drill method may be dispersed and a surface of the core layer 110 or the insulating film may be prevented from being damaged.

The wiring layer may be configured of a land or a pad connected to the via, and may be electrically connected to the adjacent circuit pattern and may be electrically connected to the wiring of the other layer through the via.

In particular, since the staggered via 130 may be used in order to maintain the rigidity of the substrate, the wiring layer made of a copper film may be patterned in a large range so as to be entirely or partially connected to the plurality of vias.

In addition, the wiring layer may be formed in a bar in a large range, which is not a path for passing a signal but may be a ground land being a basis of an electrical signal or being utilized as a ground pattern removing noise.

Meanwhile, in the wiring layer, after a copper plating is performed on the core layer 110 and/or the insulating film, an etching process is performed on remaining portions expect for a portion in which the wiring layer is formed and a portion in which the via hole is formed, and an inner via hole 111 may be formed in the core layer 110 having an opened wiring layer formed therein or a blind via hole (BVH) may be formed in the insulating film.

More specifically, a copper plating is performed on both surfaces of the core layer 110 to apply the copper film layer, the portion in which the inner via hole 111 is formed is etched to remove the copper film layer, wherein the etching is performed so that a Cu post configuring the wiring layer is left and a dam structure is formed, and a laser drilling process is performed so as to form the inner via hole 111 in the center of the Cu post.

In addition, copper plating may be performed on the inner via hole 111 penetrating through a side surface of the core layer 110 to thereby form the via, and as needed, the wiring layer may be patterned in a region expect for the Cu post.

Further, in accordance with the demand for the build-up substrate having high performance and various functions, the center of the core layer 110 may be provided with a cavity on which an electronic component 150 is capable of being mounted, wherein the electronic component 150 may be mounted on the cavity to be embedded in the core.

Here, in the electronic component 150, a multilayered ceramic capacitor (MLCC) may be positioned, and the stack via 140 and external electrode of the MLCC may be matched to be electrically connected to each other, and a solder resist layer 160 may be opened in a lower portion of the MLCC embedded in the core layer 110 so that the other external electrode is connected to the other device, and the like.

In the upper portion of the core layer 110, the Cu post may be horizontally extended to form the pad or the land, the pad or the land configuring a first wiring layer 121. In addition, a first insulating film may be applied onto the first wiring layer 121, the via hole may be formed in the first insulating film, and the copper plating may be performed to form a first via 125.

In the case of applying the above-described method, a second wiring layer and a second insulating film may be stacked on the first insulating film, and a third wiring layer and a third insulating film may be sequentially stacked thereon, thereby forming a build-up layer, and the build-up layer may be stacked as the number of wiring layers as needed.

Here, the staggered via 130 on the inner via hole 111 may be formed so that the respective center axes between upper and lower vias (for example, the first via 125 and the second via 126) are not identical to each other and the upper and lower vias adjacent to each other intersect with each other.

The upper surface at the center of the core layer 110 may be provided with the stack via 140 having linearly formed vias, wherein the respective center axes of the upper and lower vias are not deviated from a predetermined range. The stack via 140 may be electrically connected to the electronic component 150 embedded in the core layer 110 and the solder resist layer 160 may be opened so that the pad connected to the uppermost via is connected to an external device.

In the stack via 140 and the staggered via 130, the wiring layers and the interlayer insulating films serially installed on the upper surface of the core layer 110 and alternately repeated to each other are configured to be built-up, and upper and lower build-up layers may be electrically connected to each other through the via formed in the insulating film.

The stack via 140 may have a structure in which the vias are linearly positioned at the center of the core layer 110 and the staggered via 130 may be built-up at sides of the core layer 110, wherein the upper and lower vias may intersect with each other.

In particular, the wiring layer of the staggered via 130 is formed in a large range to form the ground land, and in the case of being connected to the via formed in the corresponding build-up layer, the number of vias connected to the pattern layer may be at least two, and the number of vias formed in the lower build-up layer may be the same as or more than the number of vias formed in the upper build-up layer.

In the staggered via 130 shown in FIGS. 1 and 2, a structure having two first vias 125, three second vias 126 and three third vias 127 may have a cross-section of ‘W’, and a structure having two first vias 125 and two third vias 127 may have a shape of ‘Λ’.

In addition, although not shown, the staggered via 130 in which two first vias to two third vias are included and the upper and lower vias intersect with each other in a ‘V’ shape may be provided.

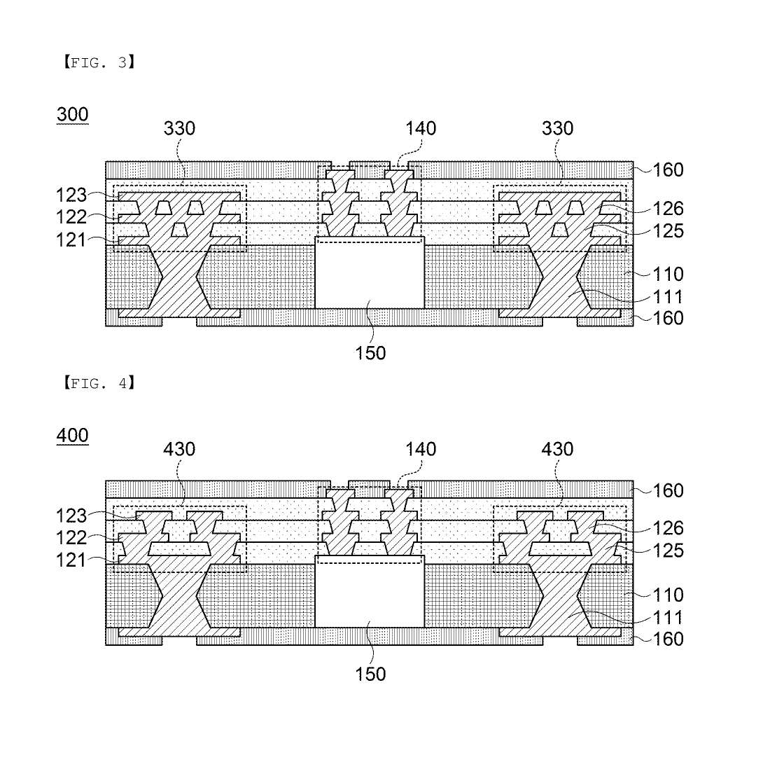

Meanwhile, as shown in FIGS. 3 and 4, the staggered vias 130 are configured of only the first to third wiring layers 123 but does not include the fourth wiring layer and the third via 127, thereby not having electrical properties, which may be utilized for increasing the rigidity of the printed circuit board rather than for transferring the signal.

The uppermost build-up layer may not configure the third via 127 and the wiring layer, and may not have open regions of the solder resist layer 160 corresponding thereto.

Therefore, the staggered vias 130 are formed only in a periphery region of the substrate, such that the signal transfer or the ground function may not be performed but the warpage generated in the periphery region of the printed circuit board may be merely prevented.

In addition, the staggered vias 130 may have a ‘W’, ‘V’ or ‘Λ’ shape as described above depending on the number and the position of vias present in each build-up layer and include three first vias 125 and two second vias 126 to have an ‘M’ shape.

Although it is described above that the staggered vias 130 are symmetrical to each other based on the stack via 140, an asymmetrical structure in which the staggered via 130 shown in FIG. 1 and the staggered via 130 shown in FIG. 2 are combined may also be applied.

Since the warpage is easily intensified at a certain portion in the asymmetrical structure, the plurality of vias may be disposed at the edge portion of the substrate in which the warpage is largely affected, the diameter of the wiring layer may be changed without increasing the number of vias to thereby increase the rigidity, and the disposition of the vias may be changed so that rigidity between left and right sides is uniform.

As set forth above, the multilayer printed circuit board according to the exemplary embodiment of the present invention may have the plurality of vias formed in the build-up layer to decrease the warpage generated in the multilayer printed circuit board.

In addition, the warpage generated in the build-up layer having the asymmetrical structure may be decreased, such that the matching between the build-up layers may be improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A multilayer printed circuit board comprising:
a stack via stacked in an upper portion of a core layer;
staggered vias formed at both sides of the stack via and stacked on the core layer; and
a solder resist layer stacked in a lower portion of the core layer and stacked on an insulating film except for open regions of the stack via and the staggered vias.

2. The multilayer printed circuit board according to claim 1, wherein in the stack via, vias adjacent to interlayer insulating films at upper and lower portions thereof are vertically connected to each other, and in the staggered vias, vias are disposed in a group in the upper portion of the core layer and wiring layers and the plurality of vias formed on the interlayer insulating films are connected to each other so as to intersect with each other.

3. The multilayer printed circuit board according to claim 1, wherein in the staggered via, diameters of vias in each insulating film are different.

4. The multilayer printed circuit board according to claim 1, wherein the staggered vias are symmetrically formed based on the stack via.

5. The multilayer printed circuit board according to claim 2, wherein the wiring layers are connected to the plurality of vias.

6. The multilayer printed circuit board according to claim 1, wherein the solder resist layer has the open regions to which the wiring layers of the stack via and the staggered vias are exposed.

7. A multilayer printed circuit board comprising:
a core layer having a cavity formed therein;
a stack via stacked on the cavity;
staggered vias formed at both sides of the stack via and stacked on the core layer; and
a solder resist layer stacked in a lower portion of the core layer and stacked on an insulating film except for open regions of the stack via.

8. The multilayer printed circuit board according to claim 7, wherein the cavity includes an electronic component embedded therein.

9. The multilayer printed circuit board according to claim 7, wherein the uppermost layer of the staggered via is provided with only the insulating film.

10. The multilayer printed circuit board according to claim 7, wherein in the stack via, vias adjacent to interlayer insulating films at upper and lower portions thereof are vertically connected to each other, and in the staggered vias, vias are disposed in a group in the upper portion of the core layer and wiring layers and the plurality of vias formed on the interlayer insulating films are connected to each other so as to intersect with each other.

11. The multilayer printed circuit board according to claim 10, wherein the wiring layer is a ground pattern.
